(19) United States
(12) Patent Application Publication
(10) Pub. No.: US 2024/0107855 A1
(43) Pub. Date: Mar. 28, 2024

(54) DISPLAY PANEL

(71) Applicant: Wuhan China Star Optoelectronics Semiconductor Display Technology Co., Ltd., Wuhan (CN)

(72) Inventors: Leitao Sun, Wuhan (CN); Wenxu Xianyu, Wuhan (CN); Chunpeng Zhang, Wuhan (CN); Zhimeng Luo, Wuhan (CN)

(21) Appl. No.: 17/621,629

(22) PCT Filed: Dec. 10, 2021
(86) PCT No.: PCT/CN2021/136934

§ 371 Date: Dec. 21, 2021

(30) Foreign Application Priority Data
Nov. 25, 2021 (CN) 202111408874.7

(51) Int. Cl. H10K 59/65; H10K 59/122

(52) U.S. Cl. CPC H10K 59/65; H10K 59/122

(57) ABSTRACT

A display panel is provided. The display panel includes: a pixel definition layer including light-emitting openings in an array distribution; a light-emitting layer disposed in the light-emitting openings; and photosensitive elements disposed above the pixel definition layer, wherein projections of the photosensitive elements on the pixel definition layer are located outside the light-emitting openings. According to the present disclosure, the photosensitive elements are disposed obliquely above the light-emitting openings of the display panel. In this way, the photosensitive elements can more effectively sense the light emitted upward from the light-emitting layer and perform signal feedback.

### FIELD OF INVENTION

The present disclosure relates to the display field, and in particular, to a display panel.

### BACKGROUND OF INVENTION

As a display panel is used for longer, the performance of internal materials gradually becomes poor, resulting in abnormal phenomena, such as display brightness reduced and uneven display, and even affecting the display performance of the display panel.

Therefore, the conventional display panel has the problems, such as brightness decay and poor brightness uniformity after long-term use, and requires to be improved.

### SUMMARY OF INVENTION

### Technical Problem

The present disclosure provides a display panel to improve the display brightness and brightness uniformity of the display panel.

### Technical Solution

The present disclosure provides a display panel. The display panel includes:
a pixel definition layer including light-emitting openings in an array distribution;
a light-emitting layer disposed in the light-emitting openings; and
photosensitive elements disposed above the pixel definition layer, wherein projections of the photosensitive elements on the pixel definition layer are located outside the light-emitting openings.

Optionally, in some embodiments of the present disclosure, each photosensitive element includes a first photosensitive electrode, a second photosensitive electrode, and a photosensitive layer located between the first photosensitive electrode and the second photosensitive electrode, wherein the first photosensitive electrode, the photosensitive layer, and the second photosensitive electrode are sequentially stacked on the pixel definition layer.

Optionally, in some embodiments of the present disclosure, the first photosensitive electrode is a transparent electrode, and the second photosensitive electrode is a highly reflective electrode.

Optionally, in some embodiments of the present disclosure, a surface of the first photosensitive electrode close to the photosensitive layer is a concave-convex surface.

Optionally, in some embodiments of the present disclosure, the display panel further includes second photosensitive electrode leads, wherein one of the second photosensitive electrode leads is disposed in a same layer as the second photosensitive electrode and is connected to the second photosensitive electrode.

Optionally, in some embodiments of the present disclosure, the display panel further includes a planarization layer, wherein the planarization layer is disposed above the pixel definition layer and is connected to the photosensitive element.

Optionally, in some embodiments of the present disclosure, a surface of the planarization layer away from the pixel definition layer is not lower than a surface of the photosensitive layer away from the pixel definition layer.

Optionally, in some embodiments of the present disclosure, the display panel further includes a first light-emitting electrode and a second light-emitting electrode respectively disposed on two sides of the light-emitting layer, wherein the second light-emitting electrode is disposed on a light-exit side of the display panel, and the second light-emitting electrode is disposed above the second photosensitive electrode and is insulated from the second photosensitive electrode.

Optionally, in some embodiments of the present disclosure, the display panel further includes a photosensitive circuit, wherein the photosensitive circuit is connected to the first photosensitive electrode.

Optionally, in some embodiments of the present disclosure, the display panel further includes a driving circuit layer, wherein the photosensitive circuit is disposed in the driving circuit layer.

Optionally, in some embodiments of the present disclosure, the photosensitive elements are disposed around the light-emitting openings.

Optionally, in some embodiments of the present disclosure, each photosensitive element has an annular opening, wherein the pixel definition layer is exposed from the annular opening.

The present disclosure provides a display panel. The display panel includes:
a pixel definition layer including light-emitting openings in an array distribution;
a light-emitting layer disposed in the light-emitting openings; and
photosensitive elements disposed above the pixel definition layer, wherein projections of the photosensitive elements on the pixel definition layer are located outside the light-emitting openings, and the photosensitive elements and the light-emitting layer are insulated from each other.

Optionally, in some embodiments of the present disclosure, each photosensitive element includes a first photosensitive electrode, a second photosensitive electrode, and a photosensitive layer located between the first photosensitive electrode and the second photosensitive electrode, wherein the first photosensitive electrode, the photosensitive layer, and the second photosensitive electrode are sequentially stacked on the pixel definition layer.

Optionally, in some embodiments of the present disclosure, the first photosensitive electrode is a transparent electrode, and the second photosensitive electrode is a highly reflective electrode.

Optionally, in some embodiments of the present disclosure, a surface of the first photosensitive electrode close to the photosensitive layer is a concave-convex surface.

Optionally, in some embodiments of the present disclosure, the display panel further includes second photosensitive electrode leads, wherein one of the second photosensitive electrode leads is disposed in a same layer as the second photosensitive electrode and is connected to the second photosensitive electrode.

Optionally, in some embodiments of the present disclosure, the display panel further includes a planarization layer, wherein the planarization layer is disposed above the pixel definition layer and is connected to the photosensitive element, and a surface of the planarization layer away from the pixel definition layer is not lower than a surface of the photosensitive layer away from the pixel definition layer.

Optionally, in some embodiments of the present disclosure, the photosensitive elements are disposed around the light-emitting openings.

Optionally, in some embodiments of the present disclosure, each photosensitive element has an annular opening, wherein the pixel definition layer is exposed from the annular opening.

### Beneficial Effects

The present disclosure provides a display panel. The display panel includes: a pixel definition layer including light-emitting openings in an array distribution; a light-emitting layer disposed in the light-emitting openings; and photosensitive elements disposed above the pixel definition layer and outside the light-emitting openings. According to the present disclosure, the photosensitive elements are disposed obliquely above the light-emitting openings of the display panel. In this way, the photosensitive elements can more effectively sense the light emitted upward from the light-emitting layer and convert the light signals to electrical signals for feedback, so as to compensate for the brightness of the display panel, thereby resolving the problems, such as brightness decay and poor brightness uniformity of the conventional display panel after long-term use.

### BRIEF DESCRIPTION OF DRAWINGS

The following describes specific implementations of the present disclosure in detail with reference to the accompanying drawings, to make the technical solutions and other beneficial effects of the present disclosure obvious.

FIG. 1 is a schematic top view of a structure of a display panel according to an embodiment of the present disclosure.

FIG. 2 is a schematic diagram of a cross-sectional structure of a display panel according to an embodiment of the present disclosure.

FIG. 3 is a first cross-sectional view of an array substrate in an AA′ direction according to an embodiment of the present disclosure.

FIG. 4 is a second cross-sectional view of an array substrate in an AA′ direction according to an embodiment of the present disclosure.

FIG. 5 is a first cross-sectional view of an array substrate in a BB′ direction according to an embodiment of the present disclosure.

FIG. 6 is a second cross-sectional view of an array substrate in a BB′ direction according to an embodiment of the present disclosure.

FIG. 7 is a third cross-sectional view of an array substrate in the BB′ direction according to an embodiment of the present disclosure.

FIG. 8 is a schematic diagram of a brightness compensation system of a display panel according to an embodiment of the present disclosure.

FIG. 9 is a schematic flowchart of a first manufacturing method for an array substrate according to an embodiment of the present disclosure.

FIG. 10 is a schematic flowchart of a second manufacturing method for an array substrate according to an embodiment of the present disclosure.

FIG. 11 is a schematic diagram of a structure of a first manufacturing method for an array substrate according to an embodiment of the present disclosure.

FIG. 12 is a schematic diagram of a structure of a second manufacturing method for an array substrate according to an embodiment of the present disclosure.

### DETAILED DESCRIPTION OF PREFERRED EMBODIMENTS

For the problem, such as brightness decay and poor brightness uniformity of the conventional display panel after long-term use, the present disclosure provides a display panel to resolve the problem.

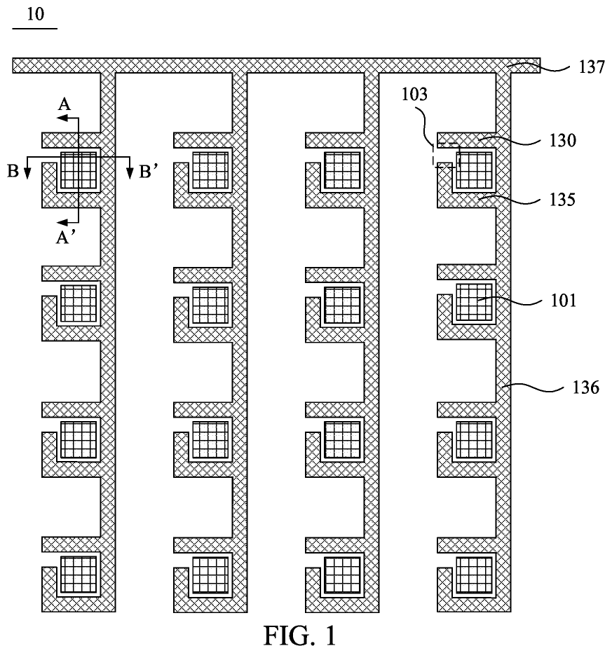

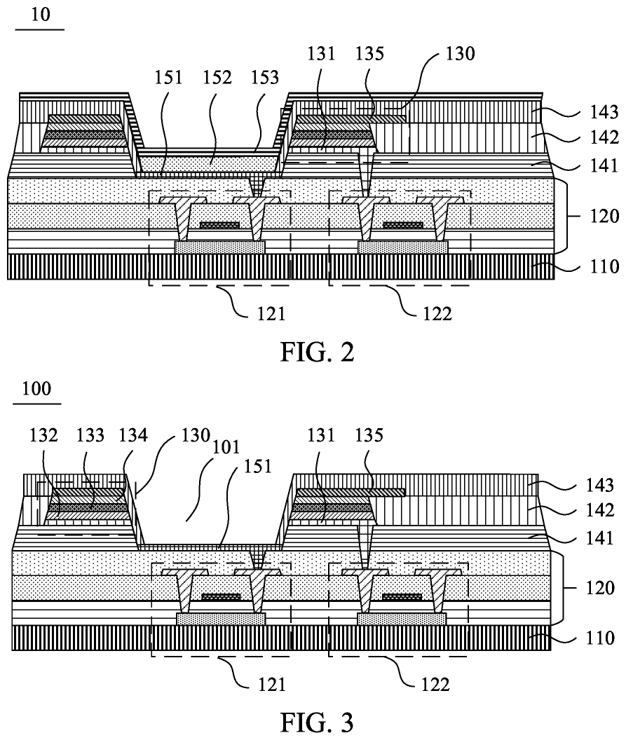

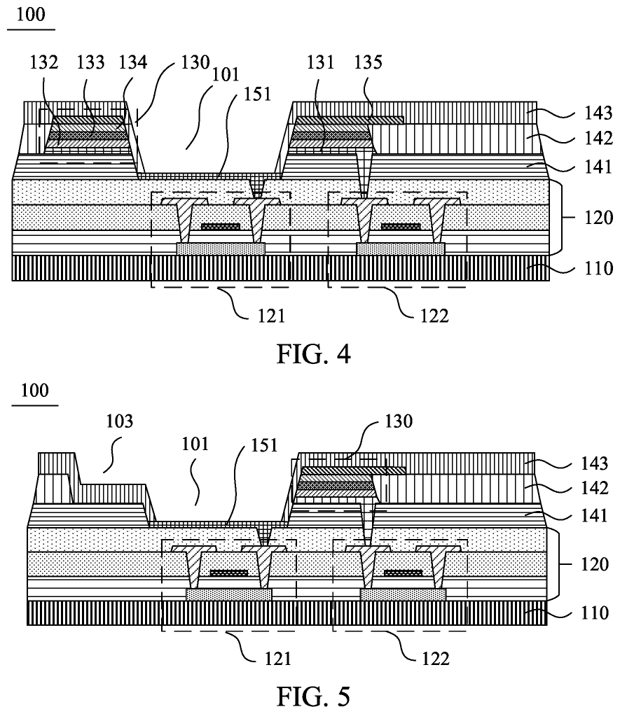

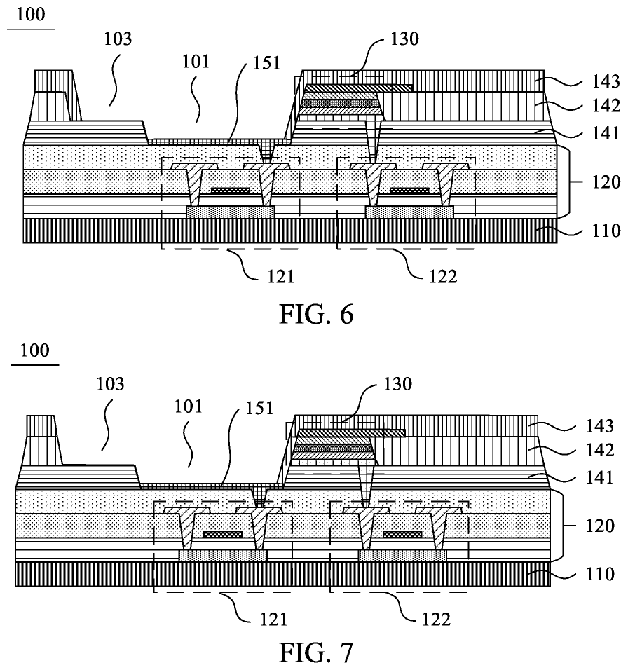

In an embodiment, refer to FIG. 1 to FIG. 7. FIG. 1 is a schematic top view of a structure of a display panel according to an embodiment of the present invention. FIG. 2 is a schematic diagram of a cross-sectional structure of a display panel according to an embodiment of the present invention. FIG. 3 is a first cross-sectional view of a display panel in an AA′ direction according to an embodiment of the present invention. FIG. 4 is a second cross-sectional view of a display panel in an AA′ direction according to an embodiment of the present invention. FIG. 5 is a first cross-sectional view of a display panel in a BB′ direction according to an embodiment of the present invention. FIG. 6 is a second cross-sectional view of a display panel in a BB′ direction according to an embodiment of the present invention. FIG. 7 is a third cross-sectional view of a display panel in a BB′ direction according to an embodiment of the present invention. As shown in the figures, the display panel provided in the embodiment of the present disclosure includes:
a pixel definition layer 141 including light-emitting openings 101 in an array distribution;
a light-emitting layer 152 disposed in the light-emitting openings 101; and
photosensitive elements 130 disposed above the pixel definition layer 141, wherein projections of the photosensitive elements 130 on the pixel definition layer 141 are located outside the light-emitting openings 101.

According to the embodiments of the present disclosure, the photosensitive elements are disposed obliquely above the light-emitting openings of the display panel. In this way, the photosensitive elements can more effectively sense the light emitted upward from the light-emitting layer and convert the light signals to electrical signals for feedback, so as to compensate for the brightness of the display panel, thereby resolving the problems, such as brightness decay and poor brightness uniformity of the conventional display panel after long-term use.

In an embodiment, referring to FIG. 2, the display panel 10 includes an array substrate 100, a light-emitting layer 152, and a second light-emitting electrode 153. The second light-emitting electrode 153 covers the array substrate 100 and the light-emitting layer 152, and the photosensitive elements 130 are disposed in the array substrate 100.

The array substrate 100 includes a thin film transistor layer 120, and the thin film transistor layer 120 is disposed on a substrate 110. The thin film transistor layer 120 includes a light-emitting circuit 121 and a photosensitive circuit 122. The light-emitting circuit 121 is electrically connected to a first light-emitting electrode 151, and the photosensitive circuit 122 is electrically connected to the photosensitive elements 130. In detail, a thin film transistor includes a semiconductor active layer, a first insulating layer, a gate layer, a second insulating layer, a source/drain layer, and a third insulating layer that are sequentially stacked on a substrate. The semiconductor active layer includes an active area of the thin film transistor in the light-emitting circuit 121 and an active area of the thin film transistor in the photosensitive circuit 122. The gate layer includes a gate electrode of the thin film transistor in the light-emitting circuit 121 and a gate electrode of the thin film transistor in the photosensitive circuit 122. The source/drain layer includes a source/drain electrode of the thin film transistor in the light-emitting circuit 121 and a source/drain electrode of the thin film transistor in the photosensitive circuit 122. The first light-emitting electrode 151 is connected to the source electrode or the drain electrode of the thin film transistor in the light-emitting circuit 121 through a via that extends through the third insulating layer, and one of the photosensitive elements 130 is connected to the source electrode or the drain electrode of the thin film transistor in the photosensitive circuit 122 through a via that extends through the third insulating layer and surrounds the pixel definition layer 141.

The array substrate 100 includes the photosensitive elements 130. Each photosensitive element 130 includes a first photosensitive electrode 131, a second photosensitive electrode 135, and a photosensitive layer located between the first photosensitive electrode 131 and the second photosensitive electrode 135. The first photosensitive electrode 131, the photosensitive layer, and the second photosensitive electrode 135 are sequentially stacked on the pixel definition layer 141. The photosensitive layer may be any of a PIN-type photodiode or a PN-type photodiode. In an implementation, as shown in FIGS. 2 to 6, the photosensitive layer is a PIN-type photodiode, and includes a P-type semiconductor layer, an N-type semiconductor layer, and an intrinsic layer (I-type layer) located between the P-type semiconductor layer and the N-type semiconductor layer. When the first photosensitive electrode 131 is an anode and the second photosensitive electrode 135 is a cathode, a layer 132, a layer 133, and a layer 134 are successively the P-type semiconductor layer, the intrinsic layer, and the N-type semiconductor layer respectively. In the present embodiment of the present disclosure, the photosensitive layer is a PIN-type photodiode, the first photosensitive electrode 131 is the anode, and the second photosensitive electrode 135 is the cathode, which are described in detail. The first photosensitive electrode 131 is connected to the source electrode or the drain electrode of the thin film transistor in the photosensitive circuit 122 through the via that extends through the third insulating layer and surrounds the pixel definition layer 141.

The first photosensitive electrode 131 is a transparent electrode. On one hand, the transparent electrode provides an anode electrical signal for the photosensitive layer. On the other hand, the transparent electrode causes, through the light emitted by the light-emitting layer in the light-emitting openings 101 of the display panel, the light emitted by the display panel to be acquired by the photosensitive layer from an underside of the photosensitive layer, thereby improving the photoelectric conversion efficiency of the photosensitive elements 130. A material of the first photosensitive electrode 131 is a transparent conductive material, including but not limited to aluminum-doped zinc oxide (AZO), indium tin oxide (ITO), and fluorine-doped tin oxide (FTO). Further, a surface of the first photosensitive electrode 131 close to the photosensitive layer is a concave-convex rough surface. The concave-convex surface reduces the reflectivity of the first photosensitive electrode 131 to the display light entering the photosensitive element 130, thereby further improving the photoelectric conversion efficiency of the photosensitive elements 130.

The second photosensitive electrode 135 is an opaque electrode. On one hand, the opaque electrode provides a cathode electrical signal for the photosensitive layer. On the other hand, the opaque electrode acts as a light-shielding layer, so as to prevent the performance of the photosensitive elements 130 from being affected adversely due to the external light entering the photosensitive elements 130, thereby improving the performance of the photosensitive elements 130. In a further aspect, the opaque electrode is used as a reflective layer, so that the light emitted from the light-emitting layer of the display panel is reflected back into the photosensitive layer by the second photosensitive electrode 135 when reaching the second photosensitive electrode 135, thereby further improving the photoelectric conversion efficiency of the photosensitive element 130. A material of the second photosensitive electrode 135 is a highly reflective conductive material, including but not limited to silver (Ag), molybdenum (Mo), and aluminum (Al).

The array substrate 100 further includes second photosensitive electrode leads. One of the second photosensitive electrode leads is disposed in a same layer as the second photosensitive electrode 135 and is connected to the second photosensitive electrode 135. As shown in FIG. 1, the second photosensitive electrode lead includes second photosensitive electrode branch leads 136 and second photosensitive electrode trunk leads 137. Each of the second photosensitive electrode branch leads 136 is connected to the second photosensitive electrode 135 in a same column, and all of the second photosensitive electrode branch leads 136 are transversely connected to one of the second photosensitive electrode trunk leads 137. Alternatively, each of the second photosensitive electrode branch leads 136 is connected to the second photosensitive electrodes 135 in a same row, and all of the second photosensitive electrode branch leads 136 are longitudinally connected to one of the second photosensitive electrode trunk leads 137. Alternatively, each of the second photosensitive electrode branch leads 136 is connected to the second photosensitive electrodes 135 in a different row or a different column, and all of the second photosensitive electrode branch leads 136 are connected to one of the second photosensitive electrode trunk leads 137. The second photosensitive electrode leads may also be a grid structure. Each of the second photosensitive electrodes 135 is connected to grid lines of the second photosensitive electrode leads.

The array substrate 100 further includes a planarization layer 142. As shown in FIGS. 2 to 7, the planarization layer 142 is disposed on the pixel definition layer 141 and is disposed in a same layer as the photosensitive elements 130. The planarization layer 142 is used to planarize a plane of the array substrate where the photosensitive layer is located, and provide a flat base for the manufacturing of the second photosensitive electrode 135 and the second photosensitive electrode lead, thereby avoiding the risk of disconnection of the second photosensitive electrode 135 and the second photosensitive electrode lead. Further, a surface of the planarization layer 142 away from the pixel definition layer 142 is flush or substantially flush with a surface of the photosensitive layer away from the pixel definition layer 141. Generally, the surface of the planarization layer 142 away from the pixel definition layer 142 is not lower than the surface of the photosensitive layer away from the pixel definition layer 141. In this way, the second photosensitive electrode leads and the second photosensitive electrode 135 are located on a same plane or substantially located on a same plane, further avoiding the risk of disconnection of the second photosensitive electrode 135 and the second photosensitive electrode lead, and improving the photoelectric conversion performance of the array substrate.

The array substrate 100 further includes an electrode insulating layer 143. As shown in FIGS. 2 to 7, the electrode insulating layer 143 is disposed on the second photosensitive electrode 135, covers the second photosensitive electrode 135, the second photosensitive electrode leads, and the planarization layer 142, and is used to isolate the second photosensitive electrode 135 from the second light-emitting electrode of the display panel, so as to avoid the electrical connection between the photosensitive element 130 and the second light-emitting electrode of the display panel. The electrode insulating layer 143 includes an insulating layer opening corresponding to the light-emitting opening 101. The first light-emitting electrode 151 is exposed from the insulating layer opening, and the light-emitting opening 101 is covered. In an implementation, as shown in FIGS. 5 and 6, the planarization layer 142 surrounds the photosensitive elements 130 and fills an area on the pixel definition layer 141 and outside the photosensitive elements 130 and the light-emitting openings 101, and the electrode insulating layer 143 further covers sides of the photosensitive elements 130. In another implementation, as shown in FIGS. 4 and 7, the planarization layer 142 fills the area on the pixel definition layer 141 and outside the photosensitive elements 130 and the light-emitting openings 101. The planarization layer 142 further covers the sides of the photosensitive elements 130, and the electrode insulating layer 143 is formed only on the second photosensitive electrode 135 and the planarization layer 142.

In an embodiment, as shown in FIGS. 1 and 2, the photosensitive elements 130 are disposed around the light-emitting openings 101. The arrangement of the photosensitive elements 130 surrounding the light-emitting openings 101 enables the light emitted from the light-emitting layer in the light-emitting openings of the display panel to the surroundings to be acquired by the photosensitive elements 130, improving the photoelectric conversion efficiency of the photosensitive elements 130. In other embodiments, the photosensitive elements 130 may alternatively be disposed in a non-circumferential manner, which is not limited herein.

In an embodiment, as shown in FIGS. 5 to 7, each photosensitive element 130 has an annular opening 103. On one hand, a blank area of the photosensitive element 130 left by the existence of the annular opening 103 reserves a lead-out position for the subsequent manufacturing of the second light-emitting electrode of the display panel, so as to avoid the risk of short circuits of the second light-emitting electrode and the photosensitive element 130. On the other hand, a film layer of the photosensitive element 130 is not disposed in the annular opening 103, thereby exposing the pixel definition layer 141. Similarly, the planarization layer 142 is not disposed in the annular opening 103, so that the pixel definition layer 141 forms a pixel definition layer step at the annular opening 103. The pixel definition layer step serves as a transition section, so as to avoid, during the subsequent manufacturing of the display panel, the problem that it is difficult for the second light-emitting electrode to climb due to the large step difference between the electrode insulating layer 143 and the first light-emitting electrode layer 151, even causing the risk of disconnection of the second light-emitting electrode. In an implementation, as shown in FIG. 5, the electrode insulating layer 143 is disposed on the pixel definition layer 141 to cover the annular opening 103. Further, the electrode insulating layer 143 may cover sides of the pixel definition layer 141 on the periphery of the light-emitting opening 101. In another implementation, as shown in FIG. 6, the electrode insulating layer 143 is not disposed in the annular opening 103. That is to say, at the position where the annular opening 103 is located, the electrode insulating layer 143 only covers the planarization layer 142 and the sides of the photosensitive element 130, to expose the pixel definition layer 141.

The light-emitting layer 152 is disposed in the light-emitting opening 101 of the pixel definition layer 141 for emitting display light. An upper surface of the light-emitting layer 152 is slightly lower than an upper surface of the pixel definition layer 141.

The second light-emitting electrode 153 is disposed on the electrode insulating layer 143 and covers the electrode insulating layer 143, the pixel definition layer 141, and the light-emitting layer 152.

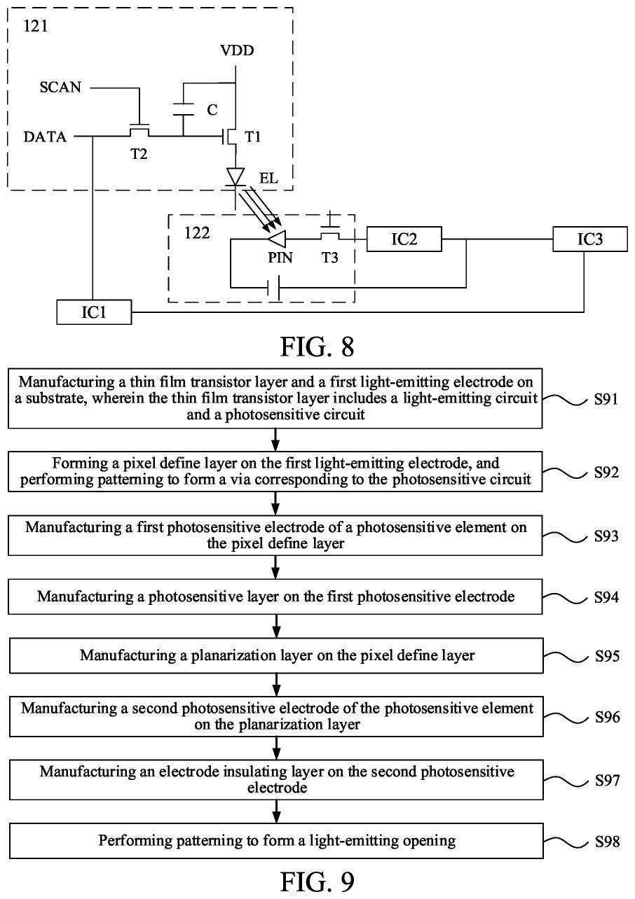

Correspondingly, an embodiment of the present disclosure further provides a brightness compensation system. The brightness compensation system performs brightness compensation for any display panel provided in the embodiment of the present disclosure. Referring to FIG. 8, FIG. 8 shows a brightness compensation system of a display panel according to an embodiment of the present disclosure. As shown in the figure, the brightness compensation system includes a light-emitting circuit 121, a photosensitive circuit 122, a light-emitting driving chip IC1, an electro-optical conversionchip IC2, and a brightness compensation chip IC3. The electro-optical conversion chip IC2 and the brightness compensation chip IC3 may be integrated as one chip.

In detail, according to the array substrate 100 and the display panel provided in the embodiment of the present disclosure, the light emitted from the light-emitting layer 152 of the display panel is irradiated on the photosensitive element 130, and the photosensitive element 130 performs photoelectric conversion on the acquired display light to generate a current signal. The current signal is transmitted to the photosensitive circuit 122, and is further transmitted to the electro-optical conversionchip IC2 under the driving of the photosensitive circuit 122. The optical conversionchip IC2 converts the acquired current signal to a light intensity signal, so as to detect the luminous intensity of the corresponding light-emitting layer 152, and transmit the detected luminous intensity to the brightness compensation chip IC3. The brightness compensation chip IC3 obtains the corresponding compensation value using an algorithm by comparing the luminous intensity with the luminosity curve, and transmits the compensation value to the light-emitting driving chip IC1. The light-emitting driving chip IC1 compensates for the corresponding sub-pixels, so as to realize the brightness compensation for the display panel. The brightness compensation system provided in the embodiment of the present disclosure uses the display panel provided in the embodiment of the present disclosure, resolving the problems, such as a low display brightness and poor brightness uniformity of the conventional display panel, and implementing real-time calibration and real-time compensation.

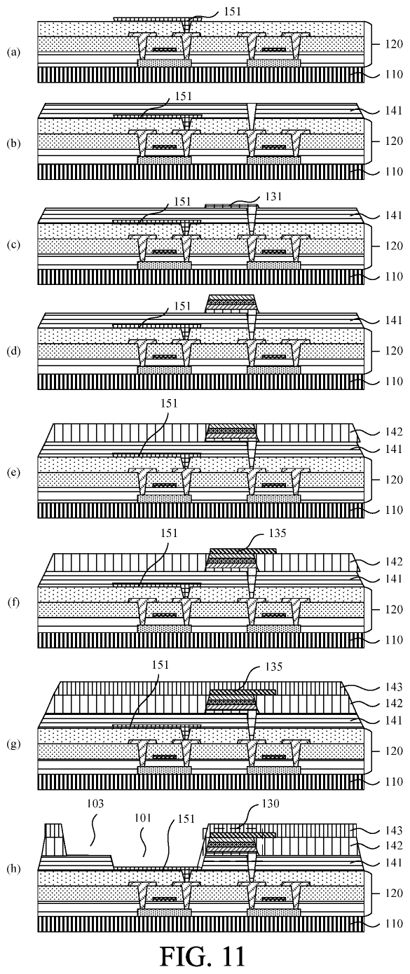

In addition, the embodiment of the present disclosure further provides a manufacturing method for an array substrate. In an embodiment, referring to FIGS. 9 and 11, FIG. 9 is a first schematic flowchart of the manufacturing method for an array substrate according to an embodiment of the present disclosure, and FIG. 11 is a schematic diagram of a first structure of the manufacturing method for an array substrate according to an embodiment of the present disclosure. As shown in FIGS. 9 and 11, the manufacturing method for an array substrate provided in the embodiment of the present disclosure includes steps below.

S91: Manufacturing a thin film transistor layer and a first light-emitting electrode on a substrate, wherein the thin film transistor layer includes a light-emitting circuit and a photosensitive circuit.

In detail, as shown in (a) of FIG. 11, a semiconductor active layer, a first insulating layer, a gate layer, a second insulating layer, a source/drain layer, and a third insulating layer are sequentially stacked on the substrate 110. The semiconductor active layer is patterned to form an active area of the thin film transistor of the light-emitting circuit and an active area of the thin film transistor of the photosensitive circuit. The gate layer is patterned to form a gate electrode of the thin film transistor of the light-emitting circuit and a gate electrode of the thin film transistor of the photosensitive circuit. The source/drain layer is patterned to form a source/drain electrode of the thin film transistor of the light-emitting circuit and a source/drain electrode of the thin film transistor of the photosensitive circuit. The first light-emitting electrode 151 is manufactured on a thin film transistor layer 120.

S92. Forming a pixel definition layer on the first light-emitting electrode, and performing patterning to form a via corresponding to the photosensitive circuit.

Details are shown in (b) of FIG. 11.

S93: Manufacturing a first photosensitive electrode of a photosensitive element on the pixel definition layer.

In detail, as shown in (c) of FIG. 11, a thin material film of the first photosensitive electrode on the pixel definition layer 141 is first formed. Then the thin material film of the first photosensitive electrode is cleaned using an alkaline parting solution, and a surface of the thin material film of the first photosensitive electrode is textured. Finally, the thin material film of the first photosensitive electrode is patterned using an etching process, to obtain a first photosensitive electrode 131, and the first photosensitive electrode 131 is connected to the photosensitive circuit through a via that extends through the pixel definition layer 141 and the third insulating layer. The material of the first photosensitive electrode 131 is a transparent conductive material, including but not limited to aluminum-doped zinc oxide (AZO), indium tin oxide (ITO), and fluorine-doped tin oxide (FTO).

S94: Manufacturing a photosensitive layer on one of the first photosensitive electrode.

In detail, as shown in (d) of FIG. 11, a P-type semiconductor layer, an intrinsic layer, and an N-type semiconductor layer are sequentially formed on the first photosensitive electrode 131, and the P-type semiconductor layer, the intrinsic layer, and the N-type semiconductor layer are patterned using an etching process to form the photosensitive layer.

S95. Manufacturing a planarization layer on the pixel definition layer.

In detail, as shown in (e) of FIG. 11, a planarization film layer is formed on the pixel definition layer 141. A thickness of the planarization film layer is a sum of thicknesses of the first photosensitive electrode 131 and the photosensitive layer, or slightly greater than a sum of thicknesses of the first photosensitive electrode 131 and the photosensitive layer. An upper surface of the planarization film layer is flush or substantially flush with an upper surface of the photosensitive layer. The planarization film layer above the photosensitive layer is removed using an etching process to obtain a patterned planarization layer 142.

S96. Manufacturing a second photosensitive electrode of the photosensitive element on the planarization layer.

Details are shown in (f) of FIG. 11. A material of the second photosensitive electrode 135 is a highly reflective conductive material, including but not limited to silver (Ag), molybdenum (Mo), and aluminum (Al).

S97. Manufacturing an electrode insulating layer on the second photosensitive electrode.

Details are shown in (g) of FIG. 11.

S98. Performing patterning to form a light-emitting opening.

In detail, as shown in (h) of FIG. 11, the electrode insulating layer 143, the planarization layer 142, and the pixel definition layer 141 are patterned using an etching process to expose the first light-emitting electrode 151 to form the light-emitting opening 101.

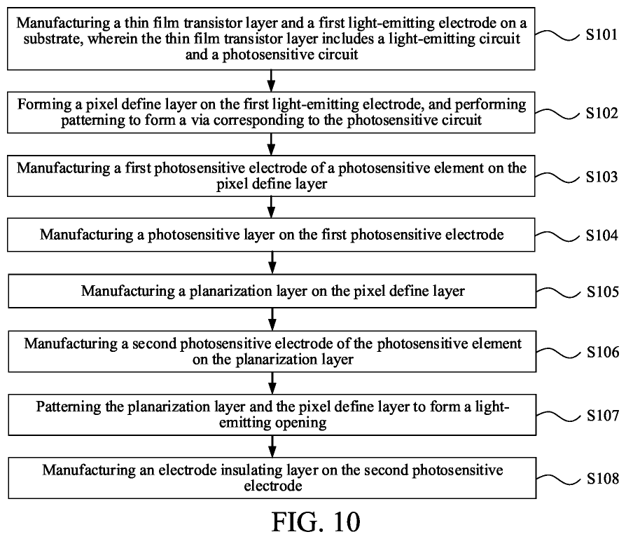

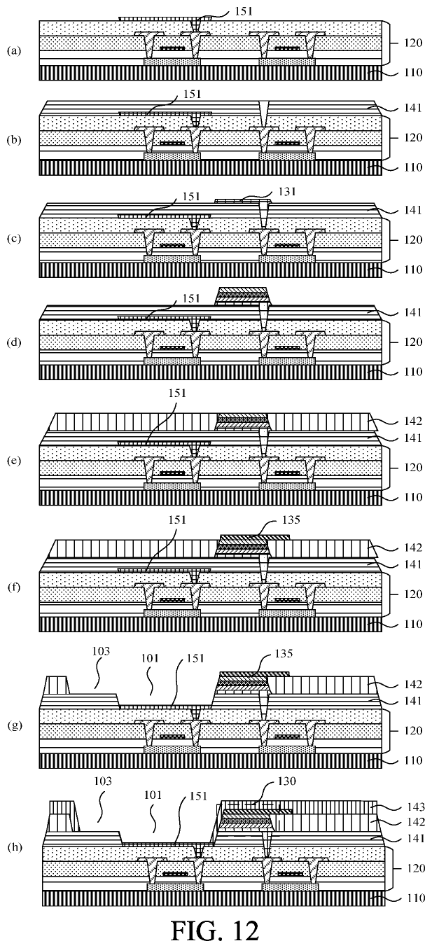

Referring to FIGS. 10 and 12, FIG. 10 is a schematic diagram of a second process of a manufacturing method for an array substrate according to an embodiment of the present disclosure, and FIG. 12 is a schematic diagram of a second structure of the manufacturing method for an array substrate according to an embodiment of the present disclosure. As shown in FIGS. 10 and 12, the manufacturing method for an array substrate provided in the embodiment of the present disclosure includes steps below.

S101: Manufacturing a thin film transistor layer and a first light-emitting electrode on a substrate, wherein the thin film transistor layer includes a light-emitting circuit and a photosensitive circuit.

S102. Forming a pixel definition layer on the first light-emitting electrode, and performing patterning to form a via corresponding to the photosensitive circuit.

S103: Manufacturing a first photosensitive electrode of a photosensitive element on the pixel definition layer.

S104: Manufacturing a photosensitive layer on one of the first photosensitive electrode.

S105. Manufacturing a planarization layer on the pixel definition layer.

S106. Manufacturing a second photosensitive electrode of the photosensitive element on the planarization layer.

S107. Patterning a planarization layer and the pixel definition layer to form a light-emitting opening. In detail, as shown in (g) of FIG. 12, the planarization layer and the pixel definition layer in an annular area of the photosensitive elements 130 and the planarization layer at the annular opening are removed using an etching process, to form the light-emitting opening 101 and the annular opening 103.

S108. Manufacturing an electrode insulating layer on the second photosensitive electrode.

Details are shown in (h) of FIG. 12.

Based on the above, the embodiment of the present disclosure provides a display panel, a brightness compensation system, and a manufacturing method for an array substrate. The display panel includes: a pixel definition layer including light-emitting openings in an array distribution; a light-emitting layer disposed in the light-emitting openings; and photosensitive elements disposed above the pixel definition layer, wherein projections of the photosensitive elements on the pixel definition layer are located outside the light-emitting openings. According to the present disclosure, the photosensitive elements are disposed obliquely above the light-emitting openings of the display panel. In this way, the photosensitive elements can more effectively sense the light emitted upward from the light-emitting layer and convert the light signals to electrical signals for feedback, so as to compensate for the brightness of the display panel, thereby resolving the problems, such as brightness decay and poor brightness uniformity of the conventional display panel after long-term use.

The display panel provided in the embodiments of the present invention are described above in detail. Specific examples are used in this specification to describe the principle and implementations of the present invention, but the foregoing descriptions of the embodiments are merely intended to help understand the method of the present invention and the core idea thereof. In addition, a person of ordinary skill in the art may make changes to the specific implementations and application scope according to the idea of the present invention. In conclusion, the content of this specification shall not be understood as a limitation to the present invention.

What is claimed is:

1. A display panel, comprising:
a pixel definition layer comprising light-emitting openings in an array distribution;
a light-emitting layer disposed in the light-emitting openings; and
photosensitive elements disposed above the pixel definition layer, wherein projections of the photosensitive elements on the pixel definition layer are located outside the light-emitting openings.

2. The display panel as claimed in claim 1, wherein each photosensitive element comprises a first photosensitive electrode, a second photosensitive electrode, and a photosensitive layer located between the first photosensitive electrode and the second photosensitive electrode, wherein the first photosensitive electrode, the photosensitive layer, and the second photosensitive electrode are sequentially stacked on the pixel definition layer.

3. The display panel as claimed in claim 2, wherein the first photosensitive electrode is a transparent electrode, and the second photosensitive electrode is a highly reflective electrode.

4. The display panel as claimed in claim 3, wherein a surface of the first photosensitive electrode close to the photosensitive layer is a concave-convex surface.

5. The display panel as claimed in claim 2, further comprising second photosensitive electrode leads, wherein one of the second photosensitive electrode leads is disposed in a same layer as the second photosensitive electrode and is connected to the second photosensitive electrode.

6. The display panel as claimed in claim 5, further comprising a planarization layer, wherein the planarization layer disposed above the pixel definition layer is connected to the photosensitive elements.

7. The display panel as claimed in claim 6, wherein a surface of the planarization layer away from the pixel definition layer is not lower than a surface of the photosensitive layer away from the pixel definition layer.

8. The display panel as claimed in claim 2, further comprising a first light-emitting electrode and a second light-emitting electrode respectively disposed on two sides of the light-emitting layer, wherein the second light-emitting electrode is disposed on a light-exit side of the display panel, and the second light-emitting electrode disposed above the second photosensitive electrode is insulated from the second photosensitive electrode.

9. The display panel as claimed in claim 2, further comprising a photosensitive circuit, wherein the photosensitive circuit is connected to the first photosensitive electrode.

10. The display panel as claimed in claim 9, further comprising a driving circuit layer, wherein the photosensitive circuit is disposed in the driving circuit layer.

11. The display panel as claimed in claim 1, wherein the photosensitive elements are disposed around the light-emitting openings.

12. The display panel as claimed in claim 11, wherein each photosensitive element has an annular opening, wherein the pixel definition layer is exposed from the annular opening.

13. A display panel, comprising:
a pixel definition layer comprising light-emitting openings in an array distribution;
a light-emitting layer disposed in the light-emitting openings; and
photosensitive elements disposed above the pixel definition layer, wherein projections of the photosensitive elements on the pixel definition layer are located outside the light-emitting openings, and the photosensitive elements and the light-emitting layer are insulated from each other.

14. The display panel as claimed in claim 13, wherein each photosensitive element comprises a first photosensitive electrode, a second photosensitive electrode, and a photosensitive layer located between the first photosensitive electrode and the second photosensitive electrode, wherein the first photosensitive electrode, the photosensitive layer, and the second photosensitive electrode are sequentially stacked on the pixel definition layer.

15. The display panel as claimed in claim 14, wherein the first photosensitive electrode is a transparent electrode, and the second photosensitive electrode is a highly reflective electrode.

16. The display panel as claimed in claim 15, wherein a surface of the first photosensitive electrode close to the photosensitive layer is a concave-convex surface.

17. The display panel as claimed in claim 14, further comprising second photosensitive electrode leads, wherein one of the second photosensitive electrode leads is disposed in a same layer as the second photosensitive electrode and is connected to the second photosensitive electrode.

18. The display panel as claimed in claim 17, further comprising a planarization layer, wherein the planarization layer is disposed above the pixel definition layer and is connected to the photosensitive elements, and a surface of the planarization layer away from the pixel definition layer is not lower than a surface of the photosensitive layer away from the pixel definition layer.

19. The display panel as claimed in claim 13, wherein the photosensitive elements are disposed around the light-emitting openings.

20. The display panel as claimed in claim 19, wherein each photosensitive element has an annular opening, wherein the pixel definition layer is exposed from the annular opening.
